(19) United States
(12) Patent Application Publication
(10) Pub. No.: US 2024/0302457 A1
(43) Pub. Date: Sep. 12, 2024

(54) MAGNETIC FIELD DETECTION SENSING DEVICE AND FLUXGATE CHIP PACKAGING STRUCTURE THEREOF

(71) Applicant: NINGBO CRRC TIMES TRANSDUCER TECHNOLOGY CO., LTD., Ningbo, Zhejiang (CN)

(72) Inventors: Yang Lv, Ningbo, Zhejiang (CN); Xiaowei Hou, Ningbo, Zhejiang (CN); Liangguang Zheng, Ningbo, Zhejiang (CN); Peng Wu, Ningbo, Zhejiang (CN); Po Zhang, Ningbo, Zhejiang (CN); Shengping Zhu, Ningbo, Zhejiang (CN)

(73) Assignee: NINGBO CRRC TIMES TRANSDUCER TECHNOLOGY CO., LTD., Ningbo, Zhejiang (CN)

(21) Appl. No.: 18/276,446

(22) PCT Filed: Jul. 15, 2021
(86) PCT No.: PCT/CN2021/106517

§ 371 Date: Aug. 8, 2023

(30) Foreign Application Priority Data
Feb. 9, 2021 (CN) 202110178693.3

(51) Int. Cl. G01R 33/04; H01L 23/498

(52) U.S. Cl. CPC G01R 33/04; H01L 23/49811

(57) ABSTRACT

The invention discloses a fluxgate chip packaging structure thereof. The fluxgate chip packaging structure comprises a fluxgate bare chip, a conductive pin, and a packaging layer wrapping the fluxgate bare chip and a pin tail of the conductive pin; and the fluxgate bare chip is electrically connected to the pin tail. Based on the fluxgate bare chip, the fluxgate chip packaging structure forms a universal chip which can be applied to a fluxgate current sensor; during use, the fluxgate bare chip can be quickly connected to the fluxgate current sensor through the conductive pin, and the fluxgate chip packaging structure can be matched with the internal structure of existing fluxgate current sensors to realize magnetic field detection of sensors; and the fluxgate chip packaging structure can completely replace traditional enameled wire probes, thus greatly reducing the probe size.

### TECHNICAL FIELD

The invention relates to the field of magnetic field detection, and particularly relates to a fluxgate chip packaging structure, and a magnetic field detection sensing device comprising the fluxgate chip packaging structure.

### DESCRIPTION OF RELATED ART

Magnetic sensors are important magnetic field detection sensing devices and widely applied to the modern industry and electronic products to sense the magnetic field intensity to measure physical parameters such as current, position, and direction.

Probes are one of the important structures of magnetic sensors. At present, most probes of magnetic sensors are enameled wire probes, which typically comprise a magnetic core and an enameled wire wound on the magnetic core. Based on such a structure, the enameled wire probes have a large size, which is not beneficial to the miniaturization of magnetic sensors.

### BRIEF SUMMARY OF THE INVENTION

The objective of the invention is to provide a fluxgate chip packaging structure, which can be used as a probe of magnetic sensors to realize magnetic field detection of the magnetic sensors and can effectively reduce the size of the probe. The other objective of the invention is to provide a magnetic field detection sensing device, which comprises the fluxgate chip packaging structure.

To fulfill the above objectives, the invention provides a fluxgate chip packaging structure, comprising a fluxgate bare chip, a conductive pin, and a packaging layer wrapping the fluxgate bare chip and a pin tail of the conductive pin, wherein the fluxgate bare chip is electrically connected to the pin tail.

Preferably, the conductive pin is specifically a metal pin, and the fluxgate bare chip and the pin tail are electrically connected through a solder wire.

Preferably, the packaging layer is specifically a packaging layer formed by a thermoset material or a thermoplastic material through plastic packaging.

Preferably, the conductive pin comprises two pins to be connected to a fluxgate current sensor.

Preferably, the PCB substrate is disposed between the fluxgate bare chip and the conductive pin, the fluxgate bare chip and the PCB substrate are electrically connected through a solder wire, and the PCB substrate and the conductive pin are electrically connected through a solder wire.

Preferably, the PCB substrate comprises a first substrate surface, the pin tail is attached and fixed to the first substrate surface, and a pin head of the conductive pin bends towards a side backing onto the PCB substrate.

Preferably, the PCB substrate comprises a second substrate surface, and the fluxgate bare chip is attached and fixed to the second substrate surface.

Preferably, the pin head of the conductive pin and the fluxgate bare chip are separately located at two ends of the PCB substrate in a length direction

The invention further provides a magnetic field detection sensing device, comprising a fluxgate current sensor, and the fluxgate chip packaging structure mentioned above.

Different from the prior art, the fluxgate chip packaging structure provided by the invention comprises the fluxgate bare chip, the conductive pin, and the packaging layer wrapping the fluxgate bare chip and the pin tail of the conductive pin; and the fluxgate bare chip is electrically connected to the pin tail.

With the fluxgate bare chip as a structural basis, the fluxgate chip packaging structure forms a universal probe which can be applied to fluxgate current sensors, and the size of the fluxgate chip packaging structure is much smaller than that of traditional enameled wire probes. The fluxgate chip packaging structure can be quickly connected to existing fluxgate current sensors through the conductive pin to be matched and compatible with the existing fluxgate current sensors, can realize magnetic field detection of sensors, and can completely replace traditional enameled wire probes.

### BRIEF DESCRIPTION OF THE SEVERAL VIEWS OF THE DRAWINGS

To more clearly describe the technical solutions of the embodiments of the invention or the prior art, drawings used for describing the embodiments of the invention or the prior art will be introduced briefly. Obviously, the drawings in the following description merely illustrate some embodiments of the invention, and those ordinarily skilled in the art can obtain other drawings according to the following ones without creative labor.

FIG. 1 is an assembly diagram of a fluxgate bare chip, a conductive pin and a PCB substrate according to one embodiment of the invention;

FIG. 2 is a structural diagram of a fluxgate chip packaging structure according to one embodiment of the invention.

In the figures: 1, fluxgate bare chip; 2, conductive pin; 21, pin tail; 22, pin head; 3, PCB substrate; 4, packaging layer.

### DETAILED DESCRIPTION OF THE INVENTION

The technical solutions of the embodiments of the invention will be clearly and completely described below in conjunction with the accompanying drawings of the embodiments of the invention. Obviously, the embodiments in the following description are merely illustrative ones, and are not all possible ones of the invention. All other embodiments obtained by those ordinarily skilled in the art based on the following ones without creative labor should fall within the protection scope of the invention.

To allow those skilled in the art to gain a better understanding of the technical solutions of the invention, the invention will be described in further detail below in conjunction with accompanying drawings and specific embodiments.

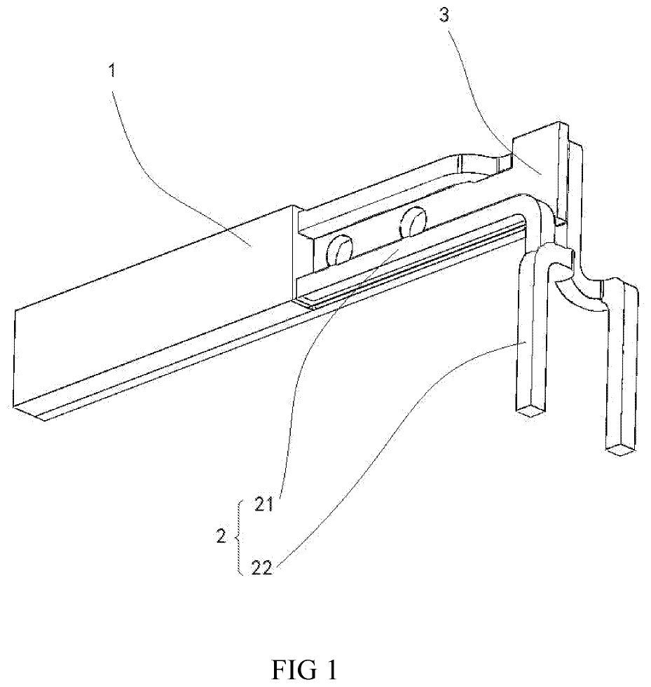

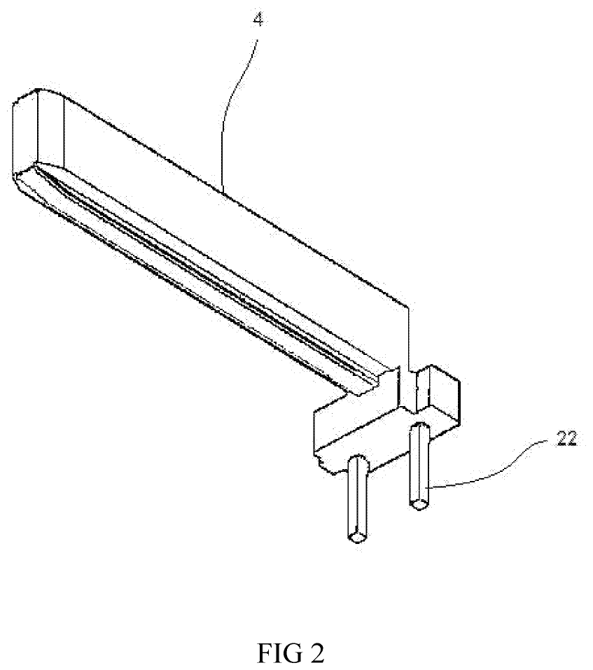

Refer to FIG. 1 which is an assembly diagram of a fluxgate bare chip, a conductive pin and a PCB substrate according to one embodiment of the invention, and FIG. 2 which is a structural diagram of a fluxgate chip packaging structure according to one embodiment of the invention.

The invention provides a fluxgate chip packaging structure, which comprises a fluxgate bare chip 1, a conductive pin 2, and a packaging layer 4; the fluxgate bare chip 1 is electrically connected to a pin tail 21 of the conductive pin 2, and a pin head 22 of the conductive pin 2 extends in a direction away from the fluxgate bare chip 1; and the packaging layer 4 wraps the fluxgate bare chip 1 and the pin tail 21 of the conductive pin 2, such that are fluxgate bare chip 1 and the pin tail 21 are sealed and insulated from the outside. Wherein, the pin head 22 of the conductive pin 2 is exposed out of the packaging layer 4 to serve as a connecting structure for realizing electrical connection between the fluxgate chip packaging structure and the outside.

The fluxgate bare chip 1 adopted in the invention may be an integrated chip which is designed and machined based on the fluxgate principle in the prior art. Due to the fact that the fluxgate bare chip 1 is electrically connected to the conductive pin 2, the fluxgate bare chip 1 can be quickly connected to other products in the outside such as a fluxgate current sensor, through the conductive pin 2, and the fluxgate chip packaging structure can be used as a probe of the fluxgate current sensor to replace traditional enameled wire probes in the prior art.

The fluxgate chip packaging structure can be used as a universal probe applied to fluxgate current sensors, and can completely replace traditional enameled wire probes and greatly reduce the size of probes; and the fluxgate chip packaging structure can be matched with the internal structure of existing fluxgate current sensors to realize magnetic field detection of sensors and engineering application of the fluxgate bare chip 1.

The fluxgate chip packaging structure provided by the invention will be further described below in conjunction with the accompanying drawings and embodiments.

In the fluxgate chip packaging structure provided by the invention, the conductive pin 2 may be a metal pin including, but not limited to, a copper pin; and corresponding to this structure, the fluxgate bare chip 1 and the pin tail 21 of the metal pin are electrically connected through a solder wire.

Clearly, when the fluxgate bare chip 1 and the pin tail 21 of the metal pin are connected through a solder pin, they should be connected according to the circuit logic of an integrated circuit in the fluxgate bare chip 1 to ensure that the fluxgate bare chip 1 and a circuit in the fluxgate current sensor can form a correct loop through the metal pin.

The packaging layer 4 adopted in the invention may be a plastic packaging layer which is formed by a thermoset material or a thermoplastic material through plastic packaging, such that the insulating and sealing performance of the fluxgate bare chip 1 are guaranteed.

In conjunction with the structure of an existing fluxgate current sensor, the conductive pin 2 adopted in the invention may comprise two pins to be connected to the fluxgate current sensor. Wherein, the two pins may bend and extend upwards as shown in FIG. 1 or downwards as shown in FIG. 1.

In a second specific embodiment of the invention, a PCB substrate 3 is disposed between the fluxgate bare chip 1 and the conductive pin 2; and the fluxgate bare chip 1 is electrically connected to the PCB substrate 3 through a solder wire, and the PCB substrate 3 is electrically connected to the conductive pin 2 through a solder pin. That is to say, the fluxgate bare chip 1 is electrically connected to the PCB substrate 3 through a first solder wire, and the PCB substrate 3 is electrically connected to the conductive pin 2 through a second solder wire.

When the fluxgate bare chip 1 is connected to a circuit of the PCB substrate 3 through a solder wire, two ends of the solder wire may be directly welded to a solder pad of the fluxgate bare chip 1 and a solder pad of the PCB substrate 3; or, the solder pad of the fluxgate bare chip 1 and the solder pad of the PCB substrate 3 may be bound through a metal wire, and are then welded and fixed through a solder wire.

Compared with the first specific embodiment, in the second specific embodiment of the invention, in order to form a correct loop by the conductive pin 2 of the fluxgate bare chip 1 and the product in the outside such as the fluxgate current sensor, the circuit logic between the fluxgate bare chip 1 and the conductive pin 2 can be adjusted through the PCB substrate 3 and a related circuit integrated on the PCB substrate 3. In this way, most existing fluxgate bare chips 1 in the prior art can be used in the second specific embodiment of the invention, thus reducing the design and machining cost of the fluxgate chip packaging structure and allowing operators to connect the fluxgate bare chip 1 and the product in the outside through the conductive pin 2 more easily.

In addition, the conductive pin 2 may be fixedly connected to the fluxgate bare chip 1 more easily through the PCB substrate 3.

Illustratively, the PCB substrate 3 may comprise a first substrate surface; the pin tail 21 of the conductive pin 2 is attached and fixed to the first substrate surface, and the pin head 22 of the conductive pin 2 bends towards a side backing onto the PCB substrate 3. Because the conductive pin 2 is bar-shaped, by attaching the pin tail 21 of the conductive pin 2 to the first substrate surface, the fixation and connecting strength of the conductive pin 2 can be improved, and operators can electrically connect the PCB substrate 3 and the pin tail 21 of the conductive pin 2 through soldering tin more conveniently.

Further, the PCB substrate 3 may comprise a second substrate surface, and the fluxgate bare chip 1 is attached and fixed to the second substrate surface.

As can be seen from above, the PCB substrate 3 adopted in the invention comprises a related circuit structure for adjusting the circuit logic between the fluxgate bare chip 1 and the conductive pin 2, and also comprises the first substrate surface and the second substrate surface for realizing relative fixation of the conducive pin 2 and the fluxgate bare chip 1. Obviously, the first substrate surface and the second substrate surface can keep away from the related circuit structure of the PCB substrate 3, for example, the first substrate surface and the second substrate surface are disposed on edges of the PCB substrate 3, and the related circuit structure of the PCB substrate 3 is disposed in the middle of the PCB substrate 3.

To facilitate operation, the pin head 22 of the conductive pin 2 and the fluxgate bare chip 1 are separately located at two ends of the PCB substrate 3 in the length direction, for example, as shown in FIG. 1, the pin head 22 of the conductive pin 2 is located at the right end of the PCB substrate 3, and the fluxgate bare chip 1 is located at the left end of the PCB substrate 3.

The invention further provides a magnetic field detection sensing device, comprising the fluxgate chip packaging structure provided by any one of the abovementioned embodiments.

The magnetic field detection sensing device further comprises a fluxgate current sensor, which may be a fluxgate current senor in the prior art. When the magnetic field detection sensing device is used, the fluxgate current sensor and the fluxgate chip packaging structure can be connected quickly through the conductive pin.

The magnetic field detection sensing device and the fluxgate chip packaging structure thereof provided by the invention are introduced in detail above. Specific embodiments are used in this specification to expound the principle and implementation of the invention, and the description of the above embodiments is merely used to help understand the method and core idea of the invention. It should be pointed out that those skilled in the art can make some improvements and modifications to the invention without deviating from the principle of the invention, and all these improvements and modifications also fall within the protection scope of the invention.

1. A fluxgate chip packaging structure, comprising a fluxgate bare chip (1), a conductive pin (2), and a packaging layer (4) wrapping the fluxgate bare chip (1) and a pin tail (21) of the conductive pin (2), wherein the fluxgate bare chip (1) is electrically connected to the pin tail (21).

2. The fluxgate chip packaging structure according to claim 1, wherein the conductive pin (2) is a metal pin, and the fluxgate bare chip (1) and the pin tail (21) are electrically connected through a solder wire.

3. The fluxgate chip packaging structure according to claim 1, wherein the packaging layer (4) is a packaging layer formed by a thermoset material or a thermoplastic material through plastic packaging.

4. The fluxgate chip packaging structure according to claim 1, wherein the conductive pin (2) comprises two pins to be connected to a fluxgate current sensor.

5. The fluxgate chip packaging structure according to claim 1, wherein the PCB substrate (3) is disposed between the fluxgate bare chip (1) and the conductive pin (2), the fluxgate bare chip (1) and the PCB substrate (3) are electrically connected through a solder wire, and the PCB substrate (3) and the conductive pin (2) are electrically connected through a solder wire.

6. The fluxgate chip packaging structure according to claim 5, wherein the PCB substrate (3) comprises a first substrate surface, the pin tail (21) is attached and fixed to the first substrate surface, and a pin head (22) of the conductive pin (2) bends towards a side backing onto the PCB substrate (3).

7. The fluxgate chip packaging structure according to claim 5, wherein the PCB substrate (3) comprises a second substrate surface, and the fluxgate bare chip (1) is attached and fixed to the second substrate surface.

8. The fluxgate chip packaging structure according to claim 5, wherein a pin head (22) of the conductive pin (2) and the fluxgate bare chip (1) are separately located at two ends of the PCB substrate (3) in a length direction.

9. A magnetic field detection sensing device, comprising a fluxgate current sensor, and the fluxgate chip packaging structure according to claim 1.
